(19) United States
(12) Patent Application Publication
(10) Pub. No.: US 2024/0380184 A1
(43) Pub. Date: Nov. 14, 2024

(54) TUNNEL JUNCTION PATTERNING FOR CONTROLLING OPTICAL AND CURRENT CONFINEMENT IN A VERTICAL-CAVITY SURFACE-EMITTING LASER

(71) Applicant: Mellanox Technologies, Ltd., Yokneam (IL)

(72) Inventors: Vladimir Iakovlev, Ecublens (CH); Yuri Berk, Kirya Tivon (IL); Isabelle Cestier, Haifa (IL); Elad Mentovich, Tel Aviv (IL)

(21) Appl. No.: 18/144,984

(22) Filed: May 9, 2023

(51) Int. Cl. H01S 5/30; H01S 5/183

(52) U.S. Cl. CPC H01S 5/3095; H01S 5/1833

(57) ABSTRACT

Some embodiments of the present invention are directed to a tunnel junction for a vertical-cavity surface-emitting laser (VCSEL) that controls optical and current confinement within the VCSEL. The tunnel junction may define an electrical current injection area and an optical aperture for the VCSEL and may include a heavily p++ doped p-type material and a heavily n++ doped n-type material disposed on the p-type material. At least a portion of the outer edges of the n-type material are etched such that the n-type material has a cross-sectional area that is less than a cross-sectional area of the p-type material. By removing a portion of n-type material near the outer edge of the tunnel junction, a sloped effective refractive index is formed, and an effective area of the tunnel junction is changed, which increases the overlap of the current density and the optical field of the VCSEL.

### FIELD OF THE INVENTION

The present invention relates to a tunnel junction for controlling optical and current confinement in a vertical-cavity surface-emitting laser (VCSEL).

### BACKGROUND

With demand for high-speed and high-volume data communication and processing increasing, equipment providers are increasingly adopting optics-based communication solutions. To meet these demands, VCSELs with enhanced optical and current confinement are being developed.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

In one aspect, the present invention is directed to a laser including a quantum well and a tunnel junction. The quantum well may be configured to emit light and define a quantum well plane, where an optical axis is perpendicular to the quantum well plane. The tunnel junction may be proximate the quantum well along the optical axis. The tunnel junction may include a p-type material proximate the quantum well and an n-type material. The p-type material may include a mesa region having a maximum outer dimension, where the mesa region has a first area in a first plane perpendicular to the optical axis. The n-type material may be disposed on the mesa region within the first area and may have a second area in a second plane parallel to the first plane, where the second area is equal to or less than the first area. The p-type material and the n-type material may be configured to provide a change in refractive index from the maximum outer dimension over a distance toward the optical axis, and the change in the refractive index may form an optical aperture of the laser.

In some embodiments, the laser may be a vertical-cavity surface-emitting laser.

In some embodiments, the laser may be a single-mode vertical-cavity surface-emitting laser.

In some embodiments, the n-type material may include a first surface adjacent the mesa region and a second surface opposite the first surface, where the n-type material has an outer dimension that increases along the optical axis from the second surface to the first surface adjacent. Additionally, or alternatively, the mesa region may have an outer dimension that increases along the optical axis from a third surface adjacent the n-type material toward the quantum well.

In some embodiments, the n-type material may include a central n-type mesa and an outer n-type region separated from the central n-type mesa by an opening. Additionally, or alternatively, the outer n-type region may have a width that is less than half of a wavelength of the light in the n-type material. In some embodiments, the opening may have a width that is less than half of a wavelength of the light in the n-type material. Additionally, or alternatively, the outer n-type region may have an external dimension equal to the maximum outer dimension of the mesa region of the p-type material.

In some embodiments, the n-type material may include a central n-type mesa, a first outer n-type region separated from the central n-type mesa by a first opening, and a second outer n-type region separated from the first outer n-type region by a second opening. Additionally, or alternatively, each of the first outer n-type region, the first opening, the second outer n-type region, and the second opening may have a respective width that is less than half of a wavelength of the light in the n-type material. In some embodiments, the second outer n-type region may have an external dimension equal to the maximum outer dimension of the mesa region of the p-type material.

In another aspect, the present invention is directed to a laser including a quantum well, a p-type material proximate the quantum well, a first tunnel junction, and a second tunnel junction. The first tunnel junction may be proximate the quantum well along a first optical axis perpendicular to the quantum well plane, where the first tunnel junction defines a first optical aperture. The second tunnel junction may be proximate the quantum well along a second optical axis perpendicular to the quantum well plane, where the second tunnel junction defines a second optical aperture, and where the second tunnel junction is laterally offset from the first tunnel junction in a direction parallel to the quantum well plane. Each of the first tunnel junction and the second tunnel junction may include a distinct portion of the p-type material forming a mesa region, where the mesa region has a maximum outer dimension and a first area in a first plane parallel to the quantum well plane. Each of the first tunnel junction and the second tunnel junction may further include an n-type material disposed on the mesa region within the maximum outer dimension, where the n-type material has a second area in a second plane parallel to the first plane and the second area is less than the first area. The first tunnel junction may increase a first overlap of (i) a first current density through the first optical aperture and (ii) a first optical field of the light through the first optical aperture. The second tunnel junction may increase a second overlap of (i) a second current density through the second optical aperture and (ii) a second optical field of the light through the second optical aperture.

In some embodiments, respective maximum outer dimensions of the mesa regions of the first tunnel junction and the second tunnel junction may be different.

In another aspect, the present invention is directed to an array of lasers including a quantum well and a p-type material proximate the quantum well. The quantum well may be configured to emit light and define a quantum well plane, and an optical axis may be perpendicular to the quantum well plane. The array of lasers may include, for each laser of the array, a tunnel junction proximate the quantum well along the optical axis, where the tunnel junction defines an optical aperture. The tunnel junction of each laser of the array may include a distinct portion of the p-type material forming a mesa region, where the mesa region has a maximum outer dimension and a first area in a first plane parallel to the quantum well plane. The tunnel junction of each laser of the array may further include an n-type material disposed on the mesa region within the maximum outer dimension, where the n-type material has a second area in a second plane parallel to the first plane, and where the second area is less than the first area. The tunnel junction of each laser of the array may increase a respective positional overlap of (i) a respective location of maximum current density through the respective optical aperture and (ii) a respective optical field of the light through the respective optical aperture.

In some embodiments, the array may be formed from a single wafer including the quantum well, the p-type material, and the respective tunnel junction of each laser of the array.

In another aspect, the present invention is directed to a method of manufacturing a laser. The method may include forming p-type epitaxial layers proximate quantum wells configured to emit light, where the quantum wells define a quantum well plane, and where an optical axis is perpendicular to the quantum well plane. The method may include forming p++ type epitaxial layers to form a p++ doped region (e.g., on the p-type epitaxial layers). The method may include forming n++ type epitaxial layers to form an n++ doped region (e.g., on the p++ doped region). The method may include etching the n++ doped region and the p++ doped region to form a tunnel junction defining an optical aperture. The tunnel junction may include p++ doped material, from the p++ doped region, including a mesa region having a maximum outer dimension, where the mesa region has a first area in a first plane parallel to the quantum well plane. The tunnel junction may include n++ doped material, from the n++ doped region, within the maximum outer dimension, where the n++ doped material has a second area in a second plane parallel to the first plane, and where the second area is less than the first area.

In some embodiments, etching the n++ doped region and the p++ doped region may include etching the n++ doped region to form the n++ doped material having an outer dimension that increases along the optical axis from a first surface opposite the mesa region to a second surface adjacent the mesa region. Additionally, or alternatively, etching the n++ doped region and the p++ doped region may include etching the p++ doped region to form the mesa region having an outer dimension that increases along the optical axis from a third surface adjacent the n++ doped material toward the quantum well.

In some embodiments, etching the n++ doped region and the p++ doped region may include etching the n++ doped region and the p++ doped region to remove, between the maximum outer dimension and a first inner dimension, (i) all of the n++ doped region and (ii) a portion of the p++ doped region. Additionally, or alternatively, etching the n++ doped region and the p++ doped region may include etching the n++ doped region to remove all of the n++ doped region between the first inner dimension and a second inner dimension. In some embodiments, etching the n++ doped region and the p++ doped region may include etching the n++ doped region to remove a portion of the n++ doped region between the second inner dimension and a third inner dimension.

In some embodiments, etching the n++ doped region and the p++ doped region may include etching the n++ doped region to remove all of the n++ doped region in an outer opening having an outer dimension radially separated from the maximum outer dimension.

In some embodiments, etching the n++ doped region and the p++ doped region may include etching the n++ doped region to remove all of the n++ doped region in two or more outer openings separate from each other, where an outer dimension of an outermost opening, of the two or more outer openings, is separated from the maximum outer dimension.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made to the accompanying drawings, wherein:

FIG. 1A illustrates a schematic cross-section of a layer structure of a laser, in accordance with an embodiment of the invention;

FIG. 1B illustrates a schematic cross-section of a portion of the layer structure of the laser of FIG. 1A before an etching step is performed, in accordance with an embodiment of the invention;

FIG. 1C illustrates a schematic cross-section of the portion of the layer structure of FIG. 1B after an etching step is performed, in accordance with an embodiment of the invention;

FIG. 1D illustrates an enlarged view of the schematic cross-section of the portion of the layer structure of FIG. 1C, in accordance with an embodiment of the invention;

FIG. 1E illustrates an overhead view of the portion of the layer structure of FIG. 1D, in accordance with an embodiment of the invention;

FIG. 2 illustrates a schematic cross-section of a portion of another layer structure of a laser, in accordance with an embodiment of the invention;

FIG. 3A illustrates a schematic cross-section of a portion of another layer structure of a laser, in accordance with an embodiment of the invention;

FIG. 3B illustrates an overhead view of the portion of the layer structure of FIG. 3A, in accordance with an embodiment of the invention;

FIG. 4 illustrates a schematic cross-section of a portion of a layer structure of a laser including two apertures formed by two tunnel junctions, in accordance with an embodiment of the invention;

FIG. 5A illustrates an overhead view of a portion of another layer structure of a laser, in accordance with an embodiment of the invention;

FIG. 5B illustrates a schematic cross-section of the portion of the layer structure of FIG. 5A;

FIG. 5C illustrates a schematic cross-section of a portion of the layer structure similar to that of FIG. 5A with an etch stop layer;

FIG. 6 illustrates an overhead view of a portion of a layer structure of an array of lasers, in accordance with an embodiment of the invention;

FIG. 7 illustrates a method for manufacturing a laser, in accordance with an embodiment of the invention; and

FIG. 8 illustrates another method for manufacturing a laser, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). As used herein, terms such as “top,” “about,” “around,” and/or the like are used for explanatory purposes in the examples provided below to describe the relative position of components or portions of components. As used herein, the terms “substantially” and “approximately” refer to tolerances within manufacturing and/or engineering standards. Like numbers refer to like elements throughout. No element, act, or instruction used herein should be construed as critical or essential unless explicitly described as such.

As noted, demand for high-speed and high-volume data communication and processing is increasing, and equipment providers are increasingly adopting optics-based communication solutions. To meet these demands, VCSELs with enhanced optical and current confinement are being developed. Such high-speed transmitters may include different types of lasers, such as light emitting diodes, top-emitting lasers, bottom-emitting lasers, edge-emitting lasers, GaAs-based lasers, InP-based lasers, directly modulated lasers, distributed-feedback lasers, and/or the like. For example, vertical-cavity surface-emitting lasers (VCSELs) may be used as high-speed transmitters for short-reach, multimode transmission (e.g., less than about 100 meters). However, such multimode VCSELs are typically unsuitable for long-reach optical fiber transmission (e.g., greater than about 100 meters) due to the optical mode dispersion of their emitted light. Conventional VCSELs designed for single mode transmission typically suffer from low output power and low modulation speed making them unsuitable for high-speed transmission. In particular, such conventional, single mode VCSELs are not capable of accurately confining the current density and the optical field of the VCSEL.

Some embodiments of the present invention are directed to a tunnel junction for a VCSEL that controls optical and electrical current confinements within the VCSEL. The tunnel junction may define an electrical current injection area and an optical aperture for the VCSEL and may include a heavily p++ doped p-type material and a heavily n++ doped n-type material disposed on the p-type material. At least a portion of the outer edges of the n-type material are etched such that the n-type material has a cross-sectional area that is less than a cross-sectional area of the p-type material. For example, outer dimensions of the n-type material and the p-type material may increase from their upper surfaces toward a quantum well of the VCSEL such that outer edges of the n-type material and the p-type material are sloped. In some embodiments, outer edges of the n-type material and the p-type material may be etched in a stepped manner. Additionally, or alternatively, one or more etched openings may be formed in the n-type material near its outer edges. For example, for a tunnel junction having a circular cross-section, one or more annular etched openings may be formed in the n-type material near its outer diameter. The widths of the etched openings of n-type material may be less than half of a wavelength in the n-type material of light emitted by the VCSEL. By removing a portion of n-type material near the outer edge of the tunnel junction, a sloped effective refractive index is formed, and an effective area of the tunnel junction is changed, which modifies the overlap of the electrical current density and the optical field of the VCSEL. Using this technique, multiple tunnel junctions may be used to form multiple optical apertures in a single device or array with accurate control of optical and electrical fields. Such tunnel junctions may be used for any type of VCSEL at any emission wavelength (e.g., between about 740 nanometers and 1,600 nanometers) which utilizes a tunnel junction approach for electrical and optical confinement.

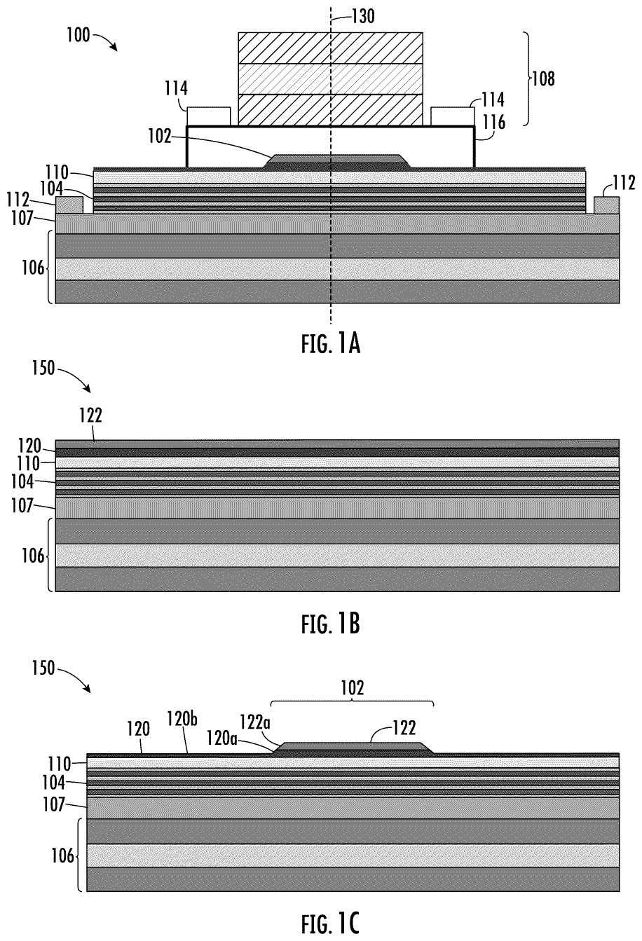

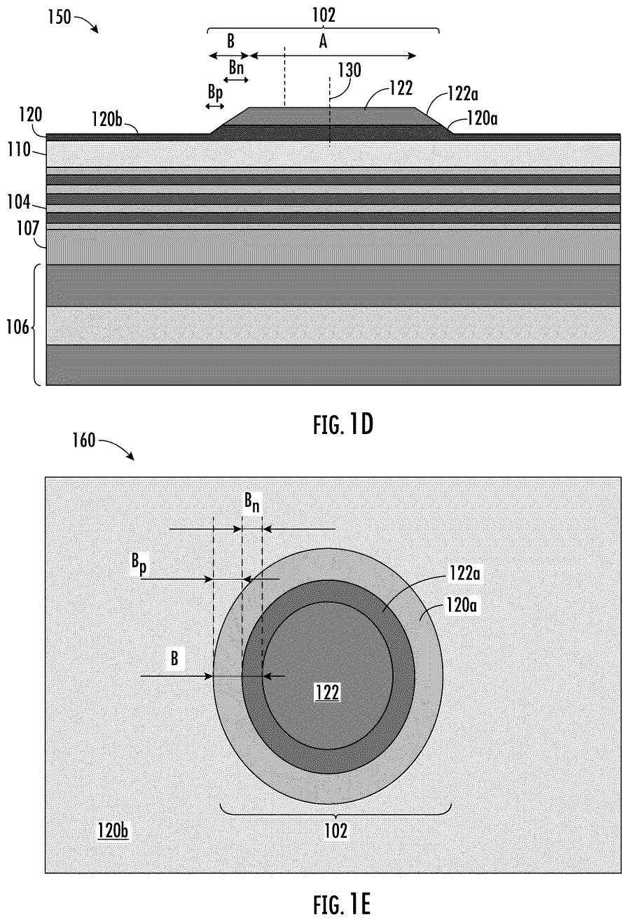

FIG. 1A illustrates a schematic cross-section of a layer structure of a laser 100, in accordance with an embodiment of the invention. In particular, the cross-section of FIG. 1A is taken in a plane that is substantially parallel to an optical axis 130 of the laser 100, the optical axis being an axis defined by the direction of light emitted by the laser. As shown in FIG. 1A, the layer structure may include a tunnel junction 102, quantum wells 104, a first mirror region 106, an n-type layer 107, a second mirror region 108, a p-type layer 110, cathode contacts 112, anode contacts 114, and another n-type layer 116. The n-type layer 107 may be positioned on the first mirror region 106. The quantum wells 104 may be positioned on the n-type layer 107, and the p-type layer 110 may be positioned on the quantum wells 104.

As shown in FIG. 1A, the tunnel junction 102 may be positioned on the p-type layer 110. As will be described in further detail with respect to FIGS. 1B-1D, the tunnel junction 102 may include a heavily p++ doped p-type material (e.g., GaAs, InGaAs, InGaAlAs, InAlAs and/or the like) and a heavily n++ doped n-type material (e.g., GaAs, InGaAs, InGaAlAs, InAlAs and/or the like), where outer portions of the heavily p++ doped p-type material and the heavily n++ doped n-type material are etched away to form the tunnel junction 102 (e.g., a tunnel junction mesa). In this regard, and as shown in FIG. 1A and described in further detail with respect to FIGS. 1C and 1D, a thin layer of the heavily p++ doped p-type material may remain on the p-type layer 110 (e.g., GaAs, InGaAs, InGaAlAs, InAlAs, InP, and/or the like) after etching in the area outside of the tunnel junction 102. In some embodiments, the layer structure may include an etch stop layer (e.g., InP) between the p-type layer 110 and the heavily p++ doped material of the tunnel junction 102.

As shown in FIG. 1A, the cathode contacts 112 may be positioned on the n-type layer 107. The cathode contacts 112 may provide electrical contacts for driving the laser 100.

The n-type layer 116 may be positioned on the tunnel junction 102 and around the tunnel junction 102 on either the heavily p++ doped p-type material, as shown in FIG. 1A, or on the p-type layer 110 if the entire heavily p++ doped p-type material in the area outside of the tunnel junction 102 is removed via etching. The anode contacts 114 may be positioned on the n-type layer 116 (e.g., InGaAlAs, InGaAsP, InP, and/or the like) and may provide electrical contacts for driving the laser 100.

As shown in FIG. 1A, the second mirror region 108 may be positioned on the n-type layer 116. In some embodiments, the first mirror region 106 and the second mirror region 108 may include distributed Bragg reflectors formed of multiple alternating dielectric material layers (e.g., GaAs, AlAs, AlGaAs, and/or the like), and may vertically confine light generated in the quantum wells 104. In this regard, the quantum wells 104 may define a quantum well plane (e.g., a horizontal plane in the orientation of FIG. 1A) and emit light parallel to the optical axis 130 of the laser 100, where the optical axis 130 is perpendicular to the quantum well plane. In some embodiments, the quantum wells 104 may be an active region of the laser 100 and may be formed from quantum well, quantum dot, and/or quantum dash layers.

As will be appreciated by one of ordinary skill in the art in light of this disclosure, the laser 100 may include other elements, such as metal contacts, one or more trenches, one or more coatings (e.g., an anti-reflective coating and/or the like), one or more insulators, one or more lenses, optical polarization control elements, and/or the like. Although the laser 100 depicted in FIG. 1A is a top-emitting VCSEL, other embodiments in accordance with the present invention may include bottom-emitting VCSELs and/or other types of VCSELs including one or more tunnel junctions formed in tunnel junction planes parallel to the optical axis 130.

FIG. 1B illustrates a schematic cross-section of a portion 150 of the layer structure of the laser 100 of FIG. 1A before an etching step is performed to create the tunnel junction 102 shown in FIG. 1A, in accordance with an embodiment of the invention. In particular, the portion 150 of the layer structure may include the quantum wells 104 positioned on the n-type layer 107, which is positioned on the first mirror region 106, as well as the p-type layer 110 positioned on the quantum wells 104. As shown in FIG. 1B, the portion 150 of the layer structure may also include a heavily p++ doped p-type layer 120 on the p-type layer 110 and a heavily n++ doped n-type layer 122 on the heavily p++ doped p-type layer 120. In some embodiments, the heavily p++ doped p-type layer 120 may be formed by heavily p++ doping an upper portion of the p-type layer 110. As shown in FIG. 1B, before an etching step is performed on the portion 150 of the layer structure, the heavily p++ doped p-type layer 120 and the heavily n++ doped n-type layer 122 extend across a width of the layer structure (e.g., extend horizontally across the layer structure in the orientation of FIG. 1A).

FIG. 1C illustrates a schematic cross-section of the portion 150 of the layer structure of FIG. 1B after the etching step is performed, in accordance with an embodiment of the invention. As shown in FIG. 1C, lateral portions (e.g., portions distal from the optical axis 130) of the heavily p++ doped p-type layer 120 and the heavily n++ doped n-type layer 122 have been etched away and/or otherwise removed to form the tunnel junction 102 (e.g., a tunnel junction mesa). In some embodiments, and as shown in FIG. 1C, the heavily p++ doped p-type layer 120 includes a mesa region 120a and a peripheral region 120b. The mesa region 120a forms a portion of the tunnel junction 102, and the peripheral region 120b includes a thin layer of heavily p++ doped p-type material (e.g., a layer that is thinner than the heavily p++ doped p-type layer 120 before etching). A mesa region 122a of the heavily n++ doped n-type layer 122 remaining after etching and/or removal forms another portion of the tunnel junction 102.

FIG. 1D illustrates an enlarged view of the schematic cross-section of the portion 150 of the layer structure of FIG. 1C, in accordance with an embodiment of the invention. As shown in FIG. 1D, the tunnel junction 102 has an outer dimension (e.g., an outer diameter) that increases from a width A at its upper surface to a width A+2×B at its lower surface adjacent the peripheral region 120b. In other words, the tunnel junction 102 has a sloped outer edge over the distance B shown in FIG. 1D.

As also shown in FIG. 1D, the mesa region 122a of the heavily n++ doped n-type layer 122 may have an outer dimension A (e.g., an outer diameter) at its upper surface and be larger at its lower surface adjacent the mesa region 120a. For example, the mesa region 122a of the heavily n++ doped n-type layer 122 may have an outer dimension that increases from a width A at its upper surface to a width A+2×Bn at its lower surface adjacent the mesa region 120a. Accordingly, the mesa region 122a has a sloped outer edge over the distance Bn shown in FIG. 1D.

As shown in FIG. 1D, the mesa region 120a of the heavily p++ doped p-type layer 120 may have an outer dimension (e.g., an outer diameter) that increases from its upper surface to its lower surface adjacent the peripheral region 120b. For example, the mesa region 120a of the heavily p++ doped p-type layer 120 may have an outer dimension that increases from a width A+2×Bn at its upper surface to a width A+2×Bn+2×Bp at its lower surface adjacent the peripheral region 120b. In other words, the mesa region 120a of the heavily p++ doped p-type layer 120 has a sloped outer edge over the distance Bp shown in FIG. 1D.

FIG. 1E illustrates an overhead view of the portion 150 of the layer structure of FIG. 1D, in accordance with an embodiment of the invention. As shown in FIG. 1E, the tunnel junction 102 has a circular shape. As will be appreciated by one of ordinary skill in the art in light of this disclosure, the tunnel junction 102 may have other non-circular shapes, such as an ellipse, a square, a triangle, a star (e.g., with five, six, seven, or more points), a quadrilateral, a pentagon, a hexagon, a heptagon, an octagon, and/or the like.

As shown by FIGS. 1D and 1E, in a plane perpendicular to the optical axis 130, the tunnel junction 102 may include a heavily n++ doped n-type layer 122 having an area that is less than an area of the mesa region 120a of the heavily p++ doped p-type layer 120. In contrast, some tunnel junctions include an n-type layer and a p-type layer having the same area in a plane perpendicular to the optical axis. By including an n-type layer having an area that is less than an area of the mesa region of the p-type layer, tunnel junctions configured in accordance with embodiments of the present invention may can control the overlap of the electrical current density of the laser and the optical field of light emitted by the laser. By increasing the positional overlap of the electrical current density of the laser and the optical field of fundamental mode, one may increase the optical power of the fundamental mode at a larger area of the tunnel junction, which due to lower electrical and thermal resistance will increase reliability of the device.

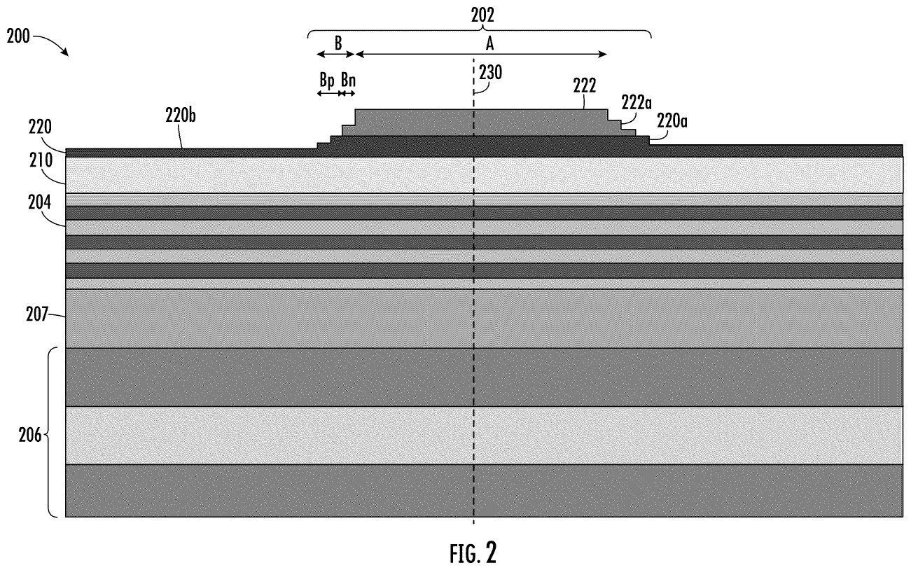

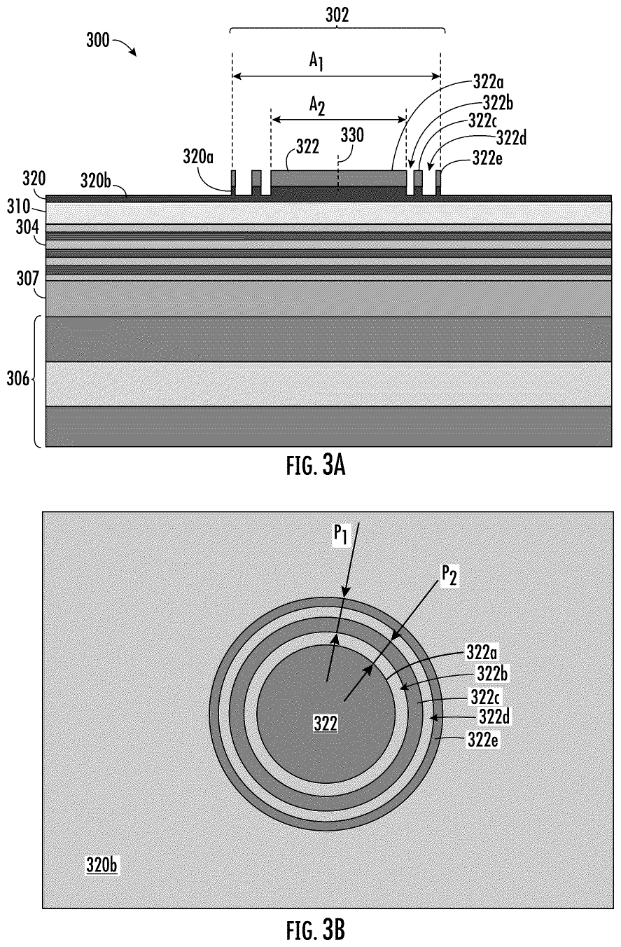

FIG. 2 illustrates a schematic cross-section of a portion 200 of another layer structure of a laser, in accordance with an embodiment of the invention. In particular, the cross-section of FIG. 2 is taken in a plane that is substantially parallel to an optical axis 230 of the laser. In some embodiments, the portion 200 of the layer structure shown in FIG. 2 may be included in a laser similar to the laser 100 shown and described herein with respect to FIG. 1A. As shown in FIG. 2, the layer structure may include a tunnel junction 202, quantum wells 204, a first mirror region 206, an n-type layer 207, a p-type layer 210, a heavily p++ doped p-type layer 220 including a mesa region 220a and a peripheral region 220b, and a heavily n++ doped n-type layer 222 including a mesa region 222a.

In some embodiments, the tunnel junction 202, quantum wells 204, the first mirror region 206, the n-type layer 207, the p-type layer 210, the heavily p++ doped p-type layer 220, the mesa region 220a, the peripheral region 220b, the heavily n++ doped n-type layer 222, and the mesa region 222a may respectively be similar to the tunnel junction 102, quantum wells 104, the first mirror region 106, the n-type layer 107, the p-type layer 110, the heavily p++ doped p-type layer 120, the mesa region 120a, the peripheral region 120b, the heavily n++ doped n-type layer 122, and the mesa region 122a shown and described herein with respect to FIGS. 1A-1E. For example, the mesa region 220a of the heavily p++ doped p-type layer 220 and the mesa region 222a of the heavily n++ doped n-type layer 122 may be formed after etching and/or removal to form the tunnel junction 202. However, as shown in FIG. 2, rather than having sloped outer edges, the mesa regions 220a and 222a may have stepped outer edges formed using multiple consecutive etches (e.g., a digital, gradual thickness variation).

As shown in FIG. 2, the tunnel junction 202 has an outer dimension (e.g., an outer diameter) that increases in a stepwise manner from a width A at its upper surface by B at its lower surface adjacent the peripheral region 220b. The mesa region 222a of the heavily n++ doped n-type layer 222 has an outer dimension (e.g., an outer diameter) that increases in a stepwise manner from a width A at its upper surface by Bn at its lower surface adjacent the mesa region 220a. The mesa region 220a of the heavily p++ doped p-type layer 220 has an outer dimension (e.g., an outer diameter) that increases in a stepwise manner from its upper surface to its lower surface adjacent the peripheral region 220b. For example, the mesa region 220a may have an outer dimension that increases from a width A+2Bn at its upper surface by Bp (or A+B) at its lower surface adjacent the peripheral region 220b.

As shown in FIG. 2, in a plane perpendicular to the optical axis 230, the tunnel junction 202 may include a heavily n++ doped n-type layer 222 having an area that is less than an area of the mesa region 220a of the heavily p++ doped p-type layer 220. Thus, the tunnel junction 202 of FIG. 2 may increase the positional overlap of the electrical current density of the laser and the optical field of a fundamental mode of light emitted by the VCSEL. By increasing the positional overlap of electrical current density of the laser and the optical field of the fundamental mode, one can increase the optical power of the fundamental mode with a larger area of the tunnel junction, which due to lower electrical and thermal resistance will increase reliability of the device. In some embodiments, etching in a stepwise or digital manner as described with respect to FIG. 2 may improve the ability to control the optical power of the fundamental mode, reduce electrical and thermal resistance, and increase reliability of the VCSEL (e.g., as compared to an analog etching manner).

FIG. 3A illustrates a schematic cross-section of a portion 300 of another layer structure of a laser, in accordance with an embodiment of the invention. In particular, the cross-section of FIG. 3A is taken in a plane that is substantially parallel to an optical axis 330 of the laser. FIG. 3B illustrates an overhead view of the portion 350 of the layer structure of FIG. 3A, in accordance with an embodiment of the invention. In some embodiments, the portion 300 of the layer structure shown in FIGS. 3A and 3B may be included in a laser similar to the laser 100 shown and described herein with respect to FIG. 1A. As shown in FIG. 3A, the layer structure may include a tunnel junction 302, quantum wells 304, a first mirror region 306, an n-type layer 307, a p-type layer 310, a heavily p++ doped p-type layer 320 including a mesa region 320a and a peripheral region 320b, and a heavily n++ doped n-type layer 322.

In some embodiments, the tunnel junction 302, quantum wells 304, the first mirror region 306, the n-type layer 307, the p-type layer 310, the heavily p++ doped p-type layer 320, the mesa region 320a, the peripheral region 320b, and the heavily n++ doped n-type layer 322 may respectively be similar to the tunnel junction 102, quantum wells 104, the first mirror region 106, the n-type layer 107, the p-type layer 110, the heavily p++ doped p-type layer 120, the mesa region 120a, the peripheral region 120b, and the heavily n++ doped n-type layer 122 shown and described herein with respect to FIGS. 1A-1E. For example, the mesa region 320a of the heavily p++ doped p-type layer 320 may be formed after etching and/or removal to form the tunnel junction 302.

However, as shown in FIGS. 3A and 3B, the heavily n++ doped n-type layer 322 may include a central mesa region 322a (e.g., a central n-type mesa), a first outer region 322c (e.g., a first outer n-type region, a first annular region, and/or the like), and a second outer region 322e (e.g., a second outer n-type region, a second annular region, and/or the like). The first outer region 322c may be separated from the central mesa region 322a by a first opening 322b, which may be formed by etching away and/or otherwise removing, for example, an annular portion of the heavily n++ doped n-type layer 322. The second outer region 322e may be separated from the first outer region 322c by a second opening 322d, which may be formed by etching away and/or otherwise removing, for example, an annular portion of the heavily n++ doped n-type layer 322.

In some embodiments, the first opening 322b, the first outer region 322c, the second opening 322d, and/or the second outer region 322e may have a width (e.g., as measured in a plane perpendicular to the optical axis 330) that is less than half a wavelength of light emitted by the quantum wells 304 in the heavily n++ doped n-type material. Additionally, or alternatively, a distance P₁ between an inner dimension (e.g., an inner diameter) of the first outer region 322c and an inner dimension (e.g., an inner diameter) of the second outer region 322e may be less than half a wavelength of light emitted by the quantum wells 304 in the heavily n++ doped n-type material. In some embodiments, a distance P₂ between an outer dimension (e.g., an outer diameter) of the first outer region 322c and an outer dimension (e.g., an outer diameter) of the second outer region 322e may be less than half a wavelength of light emitted by the quantum wells 304 in the heavily n++ doped n-type material. Using regions and openings having dimensions and distances therebetween of less than half a wavelength of light emitted by the quantum wells 304 in the heavily n++ doped n-type material avoids diffraction, which can be detrimental to optical confinement.

As shown in FIG. 3A, the tunnel junction 302 may have a maximum outer dimension A₁ (e.g., an outer diameter), and the central mesa region 322a may have a maximum outer dimension A₂ (e.g., an outer diameter). In some embodiments, a difference between the maximum outer dimension A₁ of the tunnel junction 302 and the maximum outer dimension A₂ of the central mesa region 322a may be less than half a wavelength of light emitted by the quantum wells 304 in the heavily n++ doped n-type material.

As shown in FIG. 3B, the tunnel junction 302 has a generally circular shape with a circular central mesa region, circular openings, and circular outer regions (e.g., circular outer rings). As will be appreciated by one of ordinary skill in the art in light of this disclosure, the tunnel junction 302, the central mesa region, the openings, and the outer regions may have other non-circular shapes, such as an ellipse, a square, a triangle, a star (e.g., with five, six, seven, or more points), a quadrilateral, a pentagon, a hexagon, a heptagon, an octagon, and/or the like.

As shown in FIGS. 3A and 3B, in a plane perpendicular to the optical axis 330, the tunnel junction 302 may include a heavily n++ doped n-type layer 322 having an area that is less than an area of the mesa region 320a of the heavily p++ doped p-type layer 320. Thus, the tunnel junction 302 of FIGS. 3A and 3B may increase the positional overlap of the electrical current density of the laser and the optical field of a fundamental mode of light emitted by the VCSEL. By increasing the positional overlap of electrical current density of the laser and the optical field of the fundamental mode, one can increase the optical power of the fundamental mode with a larger area of the tunnel junction, which due to lower electrical and thermal resistance will increase reliability of the device

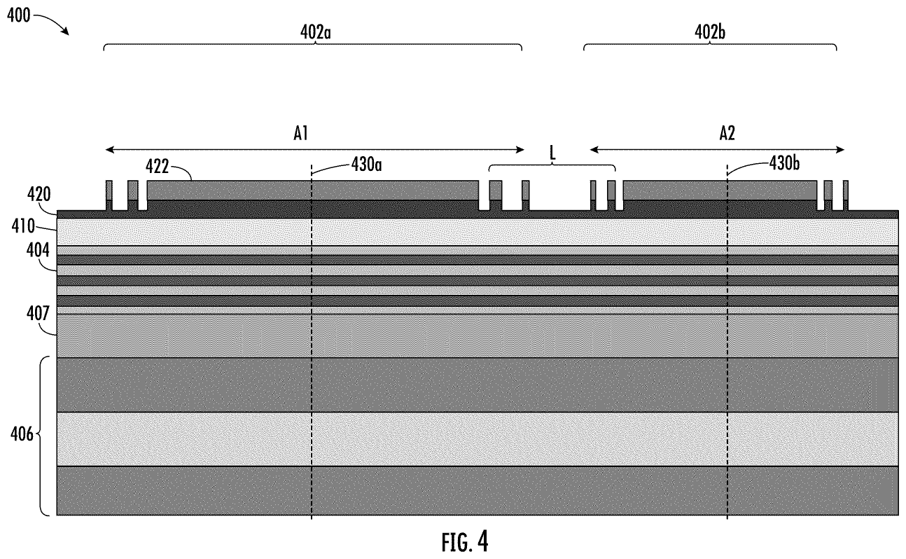

FIG. 4 illustrates a schematic cross-section of a portion 400 of a layer structure of a laser including two apertures formed by two tunnel junctions 402a and 402b, in accordance with an embodiment of the invention. In particular, the cross-section of FIG. 4 is taken in a plane that is substantially parallel to optical axes 430a and 430b of the laser. In some embodiments, the portion 400 of the layer structure shown in FIG. 4 may be included in a laser similar to the laser 100 shown and described herein with respect to FIG. 1A. As shown in FIG. 4, the layer structure may include a first tunnel junction 402a, a second tunnel junction 402b, quantum wells 404, a first mirror region 406, an n-type layer 407, a p-type layer 410, a heavily p++ doped p-type layer 420 including mesa regions for each tunnel junction and a peripheral region, and a heavily n++ doped n-type layer 422. The heavily n++ doped n-type layer 422 may include central mesa regions, first and second openings, and first and second outer regions for each of the tunnel junctions 402a and 402b.

In some embodiments, the tunnel junctions 402a and 402b, quantum wells 404, the first mirror region 406, the n-type layer 407, the p-type layer 410, the heavily p++ doped p-type layer 420, and the heavily n++ doped n-type layer 422 may respectively be similar to the tunnel junction 302, quantum wells 304, the first mirror region 306, n-type layer 307, the p-type layer 310, the heavily p++ doped p-type layer 320, and the heavily n++ doped n-type layer 322 shown and described herein with respect to FIGS. 3A and 3B. For example, the mesa regions of the heavily p++ doped p-type layer 420, the central mesa regions and the outer regions of the heavily n++ doped n-type layer 422 may be formed after etching and/or removal to form the tunnel junctions 402a and 402b. Accordingly, the tunnel junctions 402a and 402b may increase the positional overlap of electrical current density and the optical field of light emitted through each aperture (e.g., as compared to conventional tunnel junctions).

However, as shown in FIG. 4, the tunnel junctions 402a and 402b may have different maximum outer dimensions A1 and A2, respectively, and the central mesa regions may be separated by a distance L. In other words, the tunnel junctions 402a and 402b may be laterally offset from each other in a direction parallel to the quantum well plane. In some embodiments, the tunnel junctions 402a and 402b may facilitate accurate coupling of optical fields they form by optimization of the maximum outer dimensions, shapes of the apertures, and the distance L of one side of a central mesa region to another side of the other central mesa region.

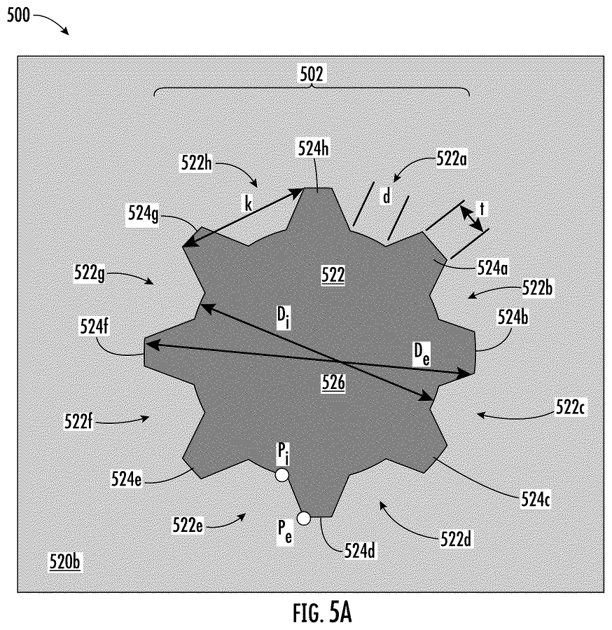

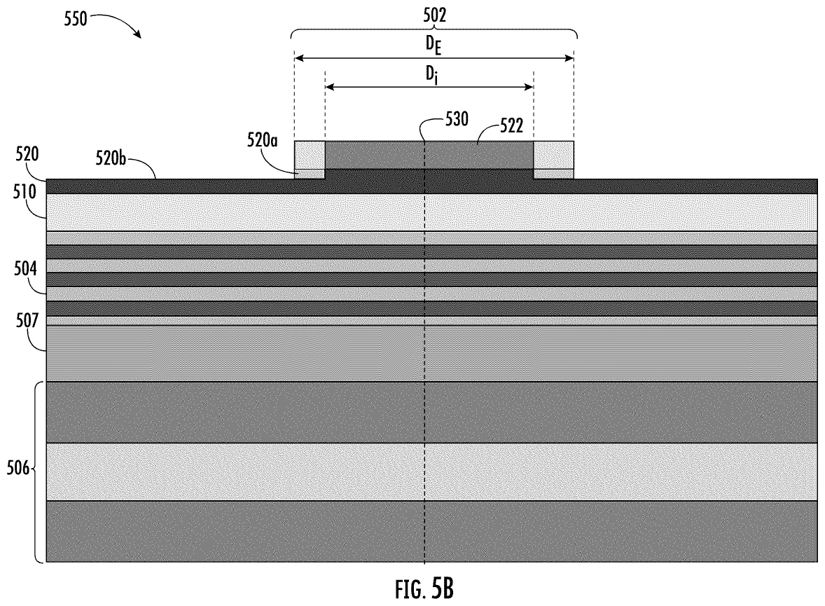

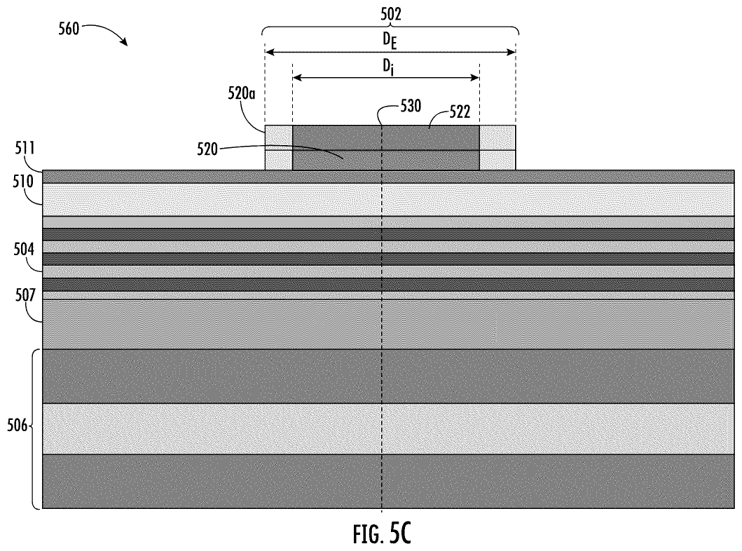

FIG. 5A illustrates an overhead view of a portion 500 of another layer structure of a laser, in accordance with an embodiment of the invention. In some embodiments, the portion 500 of the layer structure shown in FIG. 5A may be included in a laser similar to the laser 100 shown and described herein with respect to FIG. 1A. Additionally, or alternatively, beneath the portion 500 of the layer structure shown in FIG. 5A, the layer structure may include quantum wells, a first mirror region, an n-type layer, and a p-type layer respectively similar to the quantum wells 104, the first mirror region 106, the n-type layer 107, and the p-type layer 110, shown and described herein with respect to FIGS. 1A-1E.

As shown in FIG. 5A, the layer structure may include a tunnel junction 502, a peripheral region 520b of a heavily p++ doped p-type layer, and a heavily n++ doped n-type layer 522. The heavily n++ doped n-type layer 522 may include a plurality of openings 522a-522h and a plurality of projections 524a-524h formed around a central mesa region 526. The heavily p++ doped p-type layer may also include a mesa region not visible in FIG. 5A due to its positioning underneath the central mesa region 526. In some embodiments, the heavily p++ doped p-type layer, the mesa region, the peripheral region 520b, and the heavily n++ doped n-type layer 522 may respectively be similar to the heavily p++ doped p-type layer 320, the mesa region 320a, the peripheral region 320b, and the heavily n++ doped n-type layer 322 shown and described herein with respect to FIGS. 3A and 3B. For example, the mesa region of the heavily p++ doped p-type layer and the central mesa region 526 may be formed after etching and/or removal to form the tunnel junction 502. Additionally, or alternatively, the plurality of openings 522a-522h and a plurality of projections 524a-524h may also be formed around the central mesa region 526 after etching and/or removal to form the tunnel junction 502.

As shown in FIG. 5A, the tunnel junction 502 may have an inner dimension Dᵢ (e.g., an inner diameter, an outer dimension of the central mesa region 526, and/or the like) and a maximum exterior dimension Dₑ (e.g., a maximum outer diameter). The plurality of openings 522a-522h may have a width d, and the plurality of projections 524a-524h may have a width t. Each of the plurality of projections 524a-524h may be spaced around the central mesa region 526 by a distance k. A shape of each of the plurality of projections 524a-524h may be defined, in part, by a line between the points Pᵢ and Pₑ, where Pᵢ corresponds to a position at which the projection meets the central mesa region 526, and where Pₑ corresponds to a position at which the projection is farthest from the central mesa region 526.

In some embodiments, the tunnel junction 502 may include the plurality of projections 524a-524h spaced around the central mesa region 526 by a distance k, where the distance k is less than half a wavelength of light emitted by the quantum wells in the material of the heavily n++ doped n-type layer 522. That said, the distance k may not be the same between each pair of adjacent projections 524a-524h.

In some embodiments, a lateral slope of a gradual change of effective refractive index and tunnel junction resistivity from a center to an edge of an optical aperture formed by the tunnel junction 502 may be optimized by varying the inner dimension Dᵢ and/or the maximum exterior dimension Dₑ. For example, a greater difference between the inner dimension Dᵢ and the maximum exterior dimension Dₑ may correspond to a less steep lateral slope of effective refractive index and tunnel junction resistivity as compared to a tunnel junction having a smaller difference between the inner dimension Dᵢ and the maximum exterior dimension Dₑ. Additionally, or alternatively, a slope of a gradual change of lateral effective refractive index and tunnel junction resistivity from a center to an edge of an optical aperture formed by the tunnel junction 502 may be optimized by varying the shape of the plurality of projections 524a-524h defined by the line between the points Pᵢ and Pₑ.

As shown in FIG. 5A, the shapes of the openings 522a-522h and the projections 524a-524h may be selected such that there is a straight line between the point at which an opening and a projection meet (i.e., point Pᵢ in FIG. 5A) and an outermost point on the projection (i.e., point Pₑ in FIG. 5A). As also shown in FIG. 5A, the shape of the projections 524a-524h may be selected such that a transition from the straight line between such points (i.e., the line between the points Pᵢ and Pₑ in FIG. 5A) at an outermost portion of the projections 524a-524h (i.e., at point Pₑ in FIG. 5A) forms an angle of between about 90 degrees and 135 degrees. The shapes of the openings 522a-522h and the projections 524a-524h may be selected such that a transition from the straight line between such points (i.e., the line between the points Pᵢ and Pₑ in FIG. 5A) at an innermost portion of the projections (i.e., at point Pᵢ in FIG. 5A) forms an angle of between about 135 degrees and 180 degrees as shown in FIG. 5A.

FIG. 5B illustrates an example of a schematic cross-section 550 of the portion 500 of the layer structure of FIG. 5A in accordance with an embodiment of the invention. In particular, the cross-section of FIG. 5B is taken in a plane that is substantially parallel to an optical axis 530 of the laser. As shown in FIG. 5B, the layer structure may include a tunnel junction 502, quantum wells 504, a first mirror region 506, an n-type layer 507, a p-type layer 510, a heavily p++ doped p-type layer 520 including a mesa region 520a and a peripheral region 520b, and a heavily n++ doped n-type layer 522.

In some embodiments, the tunnel junction 502, quantum wells 504, the first mirror region 506, the n-type layer 507, the p-type layer 510, the heavily p++ doped p-type layer 520, the mesa region 520a, the peripheral region 520b, and the heavily n++ doped n-type layer 522 may respectively be similar to the tunnel junction 102, quantum wells 104, the first mirror region 106, the n-type layer 107, the p-type layer 110, the heavily p++ doped p-type layer 120, the mesa region 120a, the peripheral region 120b, and the heavily n++ doped n-type layer 122 shown and described herein with respect to FIGS. 1A-1E. For example, the mesa region 520a of the heavily p++ doped p-type layer 520 may be formed after etching and/or removal to form the tunnel junction 502.

FIG. 5C illustrates another example of a schematic cross-section 560 of a portion of the layer structure similar to that of FIG. 5A with an etch stop layer 511 in accordance with an embodiment of the invention. The cross section 560 of FIG. 5C may be similar to the cross section 550 of FIG. 5B except that the cross section 560 of FIG. 5C includes the etch stop layer 511. As shown in FIG. 5C, the etch stop layer 511 may be disposed between the p-type layer 510 and the heavily p++ doped p-type layer 520. As also shown in FIG. 5C, the heavily p++ doped p-type layer 520 may include only the mesa region 520a and not include a peripheral region similar to the peripheral region 520b as shown in FIG. 5B. In this regard, the etch stop layer 511 may increase the accuracy of the depth of etching performed on the heavily p++ doped p-type layer 520 and the heavily n++ doped n-type layer 522 such that all of the heavily p++ doped p-type layer 520 outside of the mesa region 520a is etched away. In some embodiments, the etch stop layer 511 may be included in other example layer structures shown and described herein to increase the accuracy of the depth of etching performed on the layers.

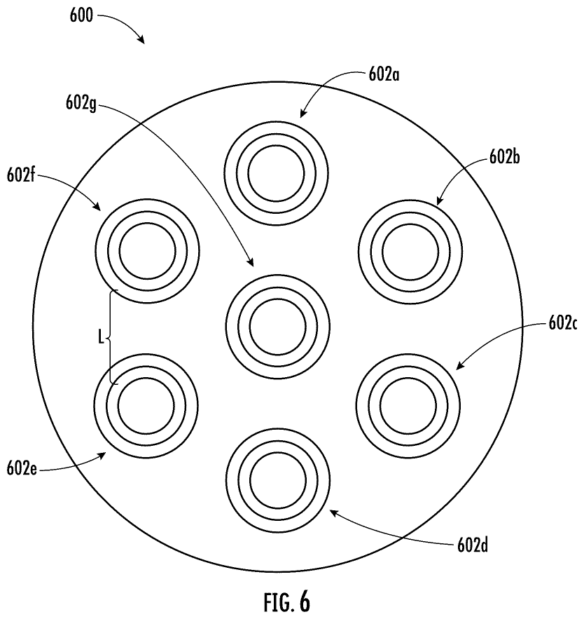

FIG. 6 illustrates an overhead view of a portion 600 of a layer structure of an array of lasers, in accordance with an embodiment of the invention. In some embodiments, the portion 600 of the layer structure shown in FIG. 6 may be included in multiple lasers similar to the laser 100 shown and described herein with respect to FIG. 1A. Additionally, or alternatively, beneath the portion 600 of the layer structure shown in FIG. 6, the layer structure may include quantum wells, a first mirror region, an n-type layer, and a p-type layer respectively similar to the quantum wells 104, the first mirror region 106, the n-type layer 107, and the p-type layer 110, shown and described herein with respect to FIGS. 1A-1E.

As shown in FIG. 6, the layer structure may include multiple tunnel junctions 602a-602g (e.g., formed from a single wafer). In some embodiments, each of the tunnel junctions 602a-602g may be similar to the tunnel junction 102 shown and described herein with respect to FIGS. 1A-1E. For example, each of the tunnel junctions 602a-602g may include a heavily p++ doped p-type layer including a mesa region and a peripheral region as well as a heavily n++ doped n-type layer. In some embodiments, the mesa region and the heavily n++ doped n-type layer of each of the tunnel junctions 602a-602g may be formed via the same etching step.

Additionally, or alternatively, in a plane perpendicular to an optical axis of each laser in the array (e.g., in the plane depicted in FIG. 6), each of the tunnel junctions 602a-602g may include a heavily n++ doped n-type layer having an area that is less than an area of the mesa region of the heavily p++ doped p-type layer. Thus, each of the tunnel junctions 602a-602g of FIG. 6 may increase the positional overlap of the location of maximum electrical current density of a laser including the tunnel junction and the optical field of light emitted by the laser as compared to conventional tunnel junctions by achieving a gradual change of effective refractive index and tunnel junction resistivity from the center to the edge of an optical aperture formed by the tunnel junction. Accordingly, each of the tunnel junctions 602a-602g may reduce the modal dispersion of a laser by filtering lateral modes, increase the optical power of the fundamental mode, enable single-mode transmission with high modulation speeds suitable for high-speed transmission, and have lower thermal resistance than oxide-based apertures.

As shown in FIG. 6, each of the tunnel junctions 602a-602g has a circular shape. As will be appreciated by one of ordinary skill in the art in light of this disclosure, each of the tunnel junctions 602a-602g may have other non-circular shapes, such as an ellipse, a square, a triangle, a star (e.g., with five, six, seven, or more points), a quadrilateral, a pentagon, a hexagon, a heptagon, an octagon, and/or the like. In some embodiments, each of the tunnel junctions 602a-602g may have a same shape. Additionally, or alternatively, some of the tunnel junctions 602a-602g may have a same shape, while others of the tunnel junctions 602a-602g may have a different shape. Furthermore, in some embodiments, each of the tunnel junctions 602a-602g may have a different shape and/or a distance L between adjacent apertures may be different. For example, the distance L may be adjusted to achieve coupling between apertures.

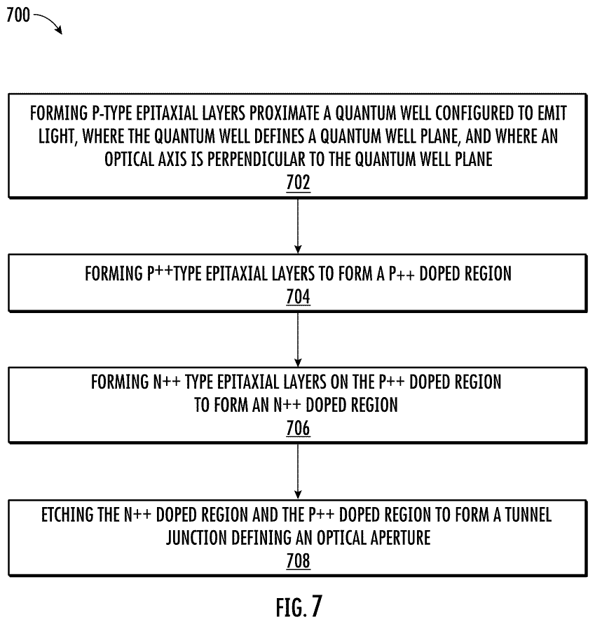

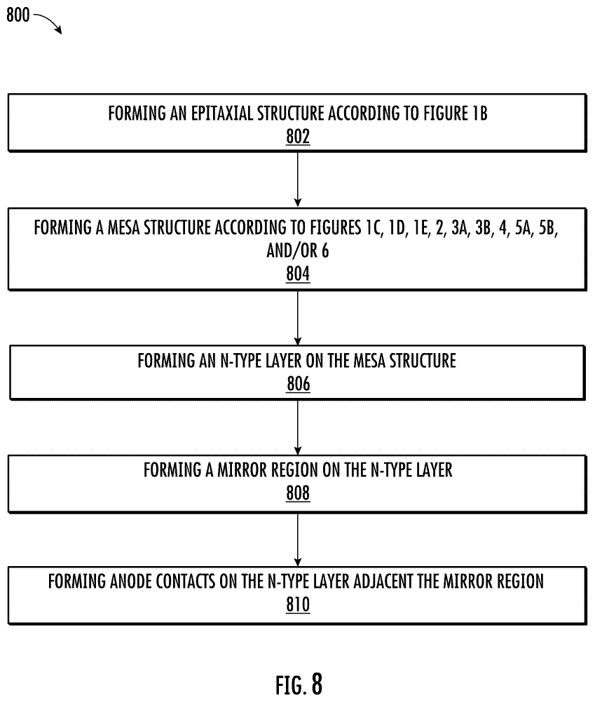

FIG. 7 illustrates a method 700 for manufacturing a laser, in accordance with an embodiment of the invention. In some embodiments, one or more steps from the method 700 may be used to manufacture one or more of the lasers and/or laser arrays described herein with respect to FIGS. 1A-6.

As shown in block 702, the method 700 may include forming p-type epitaxial layers proximate a quantum well configured to emit light, where the quantum well defines a quantum well plane and an optical axis is perpendicular to the quantum well plane. For example, the p-type epitaxial layers may be formed via deposition on an upper surface of the quantum well. In some embodiments, the p-type epitaxial layers may be InAlAs and/or InAlGaAs grown on an InP substrate. Additionally, or alternatively, the method 700 may include epitaxially growing InAlGaAs layers on an InP substrate to form the quantum well.

In some embodiments, the method 700 may include, before forming the p-type epitaxial layers, forming an n-type layer and one or more quantum wells on an InP substrate. For example, the method 700 may include forming the n-type layer and the one or more quantum wells to form a structure similar to the n-type layer 107 and the quantum wells 104 as shown and described herein with respect to FIG. 1B.

As shown in block 704, the method 700 may include forming p++ type epitaxial layers to form a p++ doped region. For example, the method 700 may include p++ doping a portion (e.g., an upper portion, a portion farthest from the quantum well in a direction parallel to the optical axis, and/or the like) of p-type epitaxial layers while forming the p-type epitaxial layers (e.g., during growth of the p-type epitaxial layers) to form the p++ doped region. In some embodiments, forming the p++ type epitaxial layers to form the p++ doped region may include using a diffusion technique, an ion implantation technique, and/or the like.

As shown in block 706, the method 700 may include forming n++ type epitaxial layers on the p++ doped region to form an n++ doped region. For example, the n++ type epitaxial layers may be formed via deposition on an upper surface of the p++ doped region, where the upper surface is opposite a lower surface of the p++ doped region proximate the quantum wells. In some embodiments, the n++ type epitaxial layers may be InAlGaAs grown on an InP substrate. Additionally, or alternatively, forming the n++ type epitaxial layers on the p++ doped region to form the n++ doped region may include n++ doping n-type epitaxial layers while forming the n-type epitaxial layers (e.g., during growth of the n-type epitaxial layers) to form the n++ doped region. In some embodiments, forming the n++ type epitaxial layers to form the n++ doped region may include using a diffusion technique, an ion implantation technique, and/or the like.

As shown in block 708, the method 700 may include etching the n++ doped region and the p++ doped region to form a tunnel junction defining an optical aperture. For example, etching the n++ doped region and the p++ doped region may include removing one or more lateral portions (e.g., radially lateral portions) of the n++ doped region and the p++ doped region to form the tunnel junction. In some embodiments, the method 700 may include wet etching (e.g., using a water-based solution) the n++ doped region and/or the p++ doped region to form the tunnel junction. Additionally, or alternatively, the method 700 may include dry etching (e.g., using reactive ion etching) the n++ doped region and/or the p++ doped region to form the tunnel junction.

In some embodiments, the method 700 may include etching the n++ doped region and the p++ doped region to form a tunnel junction that includes p++ doped material from the p++ doped region and n++ doped material from the n++ doped region. For example, the p++ doped material may include a mesa region having a maximum outer dimension, where the mesa region has a first area in a first plane parallel to the quantum well plane, and the n++ doped material may be within the maximum outer dimension and have a second area in a second plane parallel to the first plane, where the second area is less than the first area.

In some embodiments, etching the n++ doped region and the p++ doped region may include etching the n++ doped region to form the n++ doped material having an outer dimension that increases along the optical axis from a first surface opposite the mesa region to a second surface adjacent the mesa region. Additionally, or alternatively, etching the n++ doped region and the p++ doped region may include etching the p++ doped region to form the mesa region having an outer dimension that increases along the optical axis from a third surface adjacent the n++ doped material toward the quantum well. For example, the method 700 may include etching the n++ doped region and the p++ doped region to form a tunnel junction similar to the tunnel junction 102 shown and described herein with respect to FIGS. 1A-1E.

In some embodiments, the method 700 may include etching the n++ doped region and the p++ doped region to remove, between the maximum outer dimension and a first inner dimension, (i) all of the n++ doped region and (ii) a portion of the p++ doped region. The method 700 may further include etching the n++ doped region to remove all of the n++ doped region between the first inner dimension and a second inner dimension and etching the n++ doped region to remove a portion of the n++ doped region between the second inner dimension and a third inner dimension. For example, the method 700 may include etching the n++ doped region and the p++ doped region to form a tunnel junction similar to the tunnel junction 202 shown and described herein with respect to FIG. 2.

In some embodiments, the method 700 may include etching the n++ doped region to remove all of the n++ doped region in an outer opening having an outer dimension radially separated from the maximum outer dimension. For example, for a circularly shaped tunnel junction, the method 700 may include etching the n++ doped region to form an annular opening in the n++ doped region having an outer dimension radially separated from the outer diameter of the tunnel junction.

Additionally, or alternatively, the method 700 may include etching the n++ doped region and the p++ doped region to remove all of the n++ doped region in two or more outer openings separate from each other, where an outer dimension of an outermost opening, of the two or more outer openings, is separated from the maximum outer dimension. For example, for a circularly shaped tunnel junction, the method 700 may include etching the n++ doped region to form two or more annular openings in the n++ doped region separate from each other, where an outer diameter of an outermost annular opening, of the two or more annular openings, is separated from the outer diameter of the tunnel junction. As another example, the method 700 may include etching the n++ doped region and the p++ doped region to form a tunnel junction similar to the tunnel junction 302 shown and described herein with respect to FIG. 3.

In some embodiments, the method 700 may include forming another n-type layer on the tunnel junction as well as any remaining p++ doped material, an etch stop layer, and/or a p-type layer below the tunnel junction. For example, the method 700 may include forming an n-type layer similar to the n-type layer 116 shown and described herein with respect to FIG. 1A.

In some embodiments, the method 700 may include forming a mirror region on the n-type layer. For example, the method 700 may include forming a mirror region on the n-type layer similar to the second mirror region 108 shown and described herein with respect to FIG. 1A. In some embodiments, forming the mirror region may include forming multiple alternating dielectric material layers.

In some embodiments, the method 700 may include forming anode contacts on the n-type layer adjacent the mirror region. For example, the method 700 may include forming anode contacts similar to the anode contacts 114 shown and described herein with respect to FIG. 1A.

Method 700 may include additional embodiments, such as any single embodiment or any combination of embodiments described herein. Although FIG. 7 shows example blocks of method 700, in some embodiments, method 700 may include additional blocks, fewer blocks, different blocks, or differently arranged blocks than those depicted in FIG. 7. Additionally, or alternatively, two or more of the blocks of method 700 may be performed in parallel. In some embodiments, method 700 may include one or more blocks and/or steps described herein with respect to method 800 of FIG. 8.

FIG. 8 illustrates another method 800 for manufacturing a laser, in accordance with an embodiment of the invention. In some embodiments, one or more steps from the method 800 may be used to manufacture one or more of the lasers and/or laser arrays described herein with respect to FIGS. 1A-6.

As shown in block 802, the method 800 may include forming an epitaxial structure according to FIG. 1B. In some embodiments, the method 800 may include forming the first mirror region 106 on a substrate (e.g., by forming multiple alternating dielectric material layers, such as GaAs, AlAs, AlGaAs, and/or the like). Additionally, or alternatively, the method 800 may include forming the n-type layer 107 on the first mirror region 106 and forming the quantum wells 104 on the n-type layer 107. For example, the method 800 may include forming quantum well, quantum dot, and/or quantum dash layers to form the quantum wells 104.

In some embodiments, the method 800 may include forming the p-type layer 110 on the quantum wells 104 (e.g., via deposition). Additionally, or alternatively, the method 800 may include forming an etch stop layer (e.g., similar to etch stop layer 511) on the p-type layer 110. In some embodiments, the method 800 may include forming the heavily p++ doped p-type layer 120 (e.g., on the p-type layer 110, on the etch stop layer, and/or the like). In some embodiments, the method 800 may include forming the heavily n++ doped n-type layer 122 on the heavily p++ doped p-type layer 120.

As shown in block 804, the method 800 may include forming a mesa structure according to FIGS. 1C, 1D, 1E, 2, 3A, 3B, 4, 5A, 5B, 5C, and/or 6. For example, the method 800 may include etching the heavily p++ doped p-type layer 120 and the heavily n++ doped n-type layer 122 to form a mesa structure according to FIGS. 1C, 1D, 1E, 2, 3A, 3B, 4, 5A, 5B, 5C, and/or 6. In some embodiments, the etch stop layer may increase the accuracy of the depth of etching performed on the heavily p++ doped p-type layer 120 and the heavily n++ doped n-type layer 122.

As shown in block 806, the method 800 may include forming an n-type layer on the mesa structure. For example, the method 800 may include forming an n-type layer similar to the n-type layer 116 shown and described herein with respect to FIG. 1A.

As shown in block 808, the method 800 may include forming a mirror region on the n-type layer. For example, the method 800 may include forming a mirror region on the n-type layer similar to the second mirror region 108 shown and described herein with respect to FIG. 1A. In some embodiments, forming the mirror region may include forming multiple alternating dielectric material layers.

In some embodiments, the method 800 may include forming anode contacts on the n-type layer adjacent the mirror region. For example, the method 800 may include forming anode contacts similar to the anode contacts 114 shown and described herein with respect to FIG. 1A.

Method 800 may include additional embodiments, such as any single embodiment or any combination of embodiments described herein. Although FIG. 8 shows example blocks of method 800, in some embodiments, method 800 may include additional blocks, fewer blocks, different blocks, or differently arranged blocks than those depicted in FIG. 8. Additionally, or alternatively, two or more of the blocks of method 800 may be performed in parallel. In some embodiments, method 800 may include one or more blocks and/or steps described herein with respect to method 700 of FIG. 7.

As will be appreciated by one of ordinary skill in the art in view of this disclosure, the present invention may include and/or be embodied as an apparatus (including, for example, a photodetector, a device, and/or the like), as a method (including, for example, a manufacturing method, a computer-implemented process, and/or the like), or as any combination of the foregoing.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention and that this invention is not to be limited to the specific constructions and arrangements shown and described, as various other changes, combinations, omissions, modifications, and substitutions, in addition to those set forth in the above paragraphs, are possible. In light of this disclosure, those skilled in the art will appreciate that various adaptations, modifications, and combinations of the just described embodiments may be configured without departing from the scope and spirit of the invention. Therefore, it is to be understood that, within the scope of the appended claims, the invention may be practiced other than as specifically described herein.

What is claimed is:

1. A laser, comprising:
a quantum well configured to emit light, wherein the quantum well defines a quantum well plane, and wherein an optical axis is perpendicular to the quantum well plane; and
a tunnel junction proximate the quantum well along the optical axis, wherein the tunnel junction comprises:
a p-type material proximate the quantum well, wherein the p-type material comprises a mesa region having a maximum outer dimension, and wherein the mesa region has a first area in a first plane perpendicular to the optical axis; and
an n-type material disposed on the mesa region within the first area, wherein the n-type material has a second area in a second plane parallel to the first plane, and wherein the second area is equal or less than the first area;
wherein the p-type material and the n-type material are configured to provide a change in refractive index from the maximum outer dimension over a distance toward the optical axis; and
wherein the change in the refractive index forms an optical aperture of the laser.

2. The laser of claim 1, wherein the laser is a vertical-cavity surface-emitting laser.

3. The laser of claim 1, wherein the laser is a single-mode vertical-cavity surface-emitting laser.

4. The laser of claim 1, wherein the n-type material comprises a first surface adjacent the mesa region and a second surface opposite the first surface, and wherein the n-type material has an outer dimension that increases along the optical axis from the second surface to the first surface.

5. The laser of claim 4, wherein the mesa region has an outer dimension that increases along the optical axis from a third surface adjacent the n-type material toward the quantum well.

6. The laser of claim 1, wherein the n-type material comprises a central n-type mesa and an outer n-type region separated from the central n-type mesa by an opening.

7. The laser of claim 6, wherein the outer n-type region has a width that is less than half of a wavelength of the light in the n-type material.

8. The laser of claim 6, wherein the opening has a width that is less than half of a wavelength of the light in the n-type material.

9. The laser of claim 6, wherein the outer n-type region has an external dimension equal to the maximum outer dimension of the mesa region of the p-type material.

10. The laser of claim 1, wherein the n-type material comprises:
a central n-type mesa;
a first outer n-type region separated from the central n-type mesa by a first opening; and
a second outer n-type region separated from the first outer n-type region by a second opening.

11. The laser of claim 10, wherein each of the first outer n-type region, the first opening, the second outer n-type region, and the second opening have a respective width that is less than half of a wavelength of the light in the n-type material.

12. The laser of claim 10, wherein the second outer n-type region has an external dimension equal to the maximum outer dimension of the mesa region of the p-type material.

13. A laser, comprising:
a quantum well configured to emit light, wherein the quantum well defines a quantum well plane;
a p-type material proximate the quantum well;
a first tunnel junction proximate the quantum well along a first optical axis perpendicular to the quantum well plane, wherein the first tunnel junction defines a first optical aperture; and
a second tunnel junction proximate the quantum well along a second optical axis perpendicular to the quantum well plane, wherein the second tunnel junction defines a second optical aperture, and wherein the second tunnel junction is laterally offset from the first tunnel junction in a direction parallel to the quantum well plane;
wherein each of the first tunnel junction and the second tunnel junction comprises:
a distinct portion of the p-type material forming a mesa region, wherein the mesa region has a maximum outer dimension, and wherein the mesa region has a first area in a first plane parallel to the quantum well plane; and
an n-type material disposed on the mesa region within the maximum outer dimension, wherein the n-type material has a second area in a second plane parallel to the first plane, and wherein the second area is less than the first area;
wherein the first tunnel junction increases a first overlap of (i) a first current density through the first optical aperture and (ii) a first optical field of the light through the first optical aperture; and
wherein the second tunnel junction increases a second overlap of (i) a second current density through the second optical aperture and (ii) a second optical field of the light through the second optical aperture.

14. The laser of claim 13, wherein respective maximum outer dimensions of the mesa regions of the first tunnel junction and the second tunnel junction are different.

15. An array of lasers, comprising:
a quantum well configured to emit light, wherein the quantum well defines a quantum well plane, and wherein an optical axis is perpendicular to the quantum well plane;
a p-type material proximate the quantum well; and
for each laser of the array:
a tunnel junction proximate the quantum well along the optical axis, wherein the tunnel junction defines an optical aperture, wherein the tunnel junction comprises:
a distinct portion of the p-type material forming a mesa region, wherein the mesa region has a maximum outer dimension, and wherein the mesa region has a first area in a first plane parallel to the quantum well plane; and
an n-type material disposed on the mesa region within the maximum outer dimension, wherein the n-type material has a second area in a second plane parallel to the first plane, and wherein the second area is less than the first area;
wherein each tunnel junction increases a respective positional overlap of (i) a respective location of maximum current density through the respective optical aperture and (ii) a respective optical field of the light through the respective optical aperture.

16. The array of claim 15, wherein the array is formed from a single wafer comprising the quantum well, the p-type material, and the respective tunnel junction of each laser of the array.

17. A method of manufacturing a laser, the method comprising:
forming p-type epitaxial layers proximate quantum wells configured to emit light, wherein the quantum wells define a quantum well plane, and wherein an optical axis is perpendicular to the quantum well plane;
forming p++ type epitaxial layers to form a p++ doped region;
forming n++ type epitaxial layers to form an n++ doped region;
etching the n++ doped region and the p++ doped region to form a tunnel junction defining an optical aperture, wherein the tunnel junction comprises:
p++ doped material, from the p++ doped region, comprising a mesa region having a maximum outer dimension, wherein the mesa region has a first area in a first plane parallel to the quantum well plane; and
n++ doped material, from the n++ doped region, within the maximum outer dimension, wherein the n++ doped material has a second area in a second plane parallel to the first plane, and wherein the second area is less than the first area.

18. The method of claim 17, wherein etching the n++ doped region and the p++ doped region comprises etching the n++ doped region to form the n++ doped material having an outer dimension that increases along the optical axis from a first surface opposite the mesa region to a second surface adjacent the mesa region.

19. The method of claim 18, wherein etching the n++ doped region and the p++ doped region comprises etching the p++ doped region to form the mesa region having an outer dimension that increases along the optical axis from a third surface adjacent the n++ doped material toward the quantum wells.

20. The method of claim 17, wherein etching the n++ doped region and the p++ doped region comprises:
etching the n++ doped region and the p++ doped region to remove, between the maximum outer dimension and a first inner dimension, (i) all of the n++ doped region and (ii) a portion of the p++ doped region;
etching the n++ doped region to remove all of the n++ doped region between the first inner dimension and a second inner dimension; and
etching the n++ doped region to remove a portion of the n++ doped region between the second inner dimension and a third inner dimension.

21. The method of claim 17, wherein etching the n++ doped region and the p++ doped region comprises etching the n++ doped region to remove all of the n++ doped region in an outer opening having an outer dimension radially separated from the maximum outer dimension.

22. The method of claim 17, wherein etching the n++ doped region and the p++ doped region comprises etching the n++ doped region to remove all of the n++ doped region in two or more outer openings separate from each other, wherein an outer dimension of an outermost opening, of the two or more outer openings, is separated from the maximum outer dimension.
